(19) United States
(12) Patent Application Publication
(10) Pub. No.: US 2005/0215026 A1
(43) Pub. Date: Sep. 29, 2005

(54) Method for producing semiconductor device

(75) Inventors: Takuo Ohashi, Tokyo (JP); Taishi Kubota, Tokyo (JP); Susumu Sakurai, Tokyo (JP); Takayuki Kanda, Tokyo (JP)

Correspondence Address: MCGINN & GIBB, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 11/087,585

(22) Filed: Mar. 24, 2005

(30) Foreign Application Priority Data
Mar. 25, 2004 (JP) 2004-89887

(51) Int. Cl. H01L 21/76

(52) U.S. Cl. 438/424; 438/433

(57) ABSTRACT

With respect to nitriding of an oxide film on an inner wall of a trench, a method for producing a semiconductor device is provided, the method preventing the characteristic deterioration of the semiconductor device by controlling and optimizing peak nitrogen concentration in an oxide film to reduce the stress and to suppress the threshold voltage shift due to the positive charge of nitrogen.

This application claims priority to prior Japanese patent application JP 2004-89887, the disclosure of which is incorporated herein by reference.

### BACKGROUND OF THE INVENTION

1. Field of the Invention

The present invention relates to a method for producing an isolation region for isolating elements from each other in a semiconductor device.

2. Description of the Related Art

Shallow trench isolation (STI) has been known as a process for isolating elements from each other in a semiconductor device. As shown in FIG. 12, the STI is performed as follows: A nitride film 2 is grown on a silicon substrate 1. A trench 3 is formed by etching. The inner walls of the trench 3 are thermally oxidized to form inner-wall oxide films 4. Another oxide film is formed in the trench by plasma oxidation so as to be embedded in the entire trench. In this way, the isolation region is produced.

In this process, the oxide films 4 each having a thermal expansion coefficient different from that of the silicon substrate 1 are provided on the inner walls. This causes high strain in the silicon substrate 1, thus resulting in a dislocation defect in the silicon crystal. The dislocation defect in the silicon substrate functions as a leakage path; hence, an off leakage current is increased. This impairs the characteristics of the semiconductor device, that is, this causes, for example, an increase in standby current or the deterioration of the hold (refresh) characteristics on dynamic random-access memories (DRAMs). Techniques in which by nitriding the oxide films 4 provided on the inner walls, the strain in the silicon substrate is reduced to prevent the occurrence of the dislocation defect and the leakage current have been known as measures to prevent the characteristic deterioration. Japanese Unexamined Patent Application Publications Nos. 2000-082808 and 2001-135720 are examples of the related art.

### SUMMARY OF THE INVENTION

In such a process for reducing the stress on the silicon substrate by nitriding the oxide films on the inner walls, excessively high nitrogen concentrations in the resulting oxynitride films reduce the threshold voltages (Vth) of the respective transistors due to the effect of the positive charge of nitrogen. As a result, new problems in which the reduction in threshold voltage increases the leakage current to impair the hold characteristics of the DRAM have been found.

Accordingly, with respect to STI, in nitriding oxide films on inner walls of a trench, it is an object of the present invention to provide a method for producing a semiconductor device, the method preventing the characteristic deterioration of the semiconductor device by controlling peak nitrogen concentration in each oxide film to reduce the stress and to suppress the threshold voltage shift due to the positive charge of nitrogen. It is also an object of the present invention to provide the semiconductor device produced by the method.

According to a first aspect of the present invention, a method for producing a semiconductor device includes a step of nitriding an oxide film on an inner wall of a trench, the lower limit of the peak nitrogen concentration being set so that stress on a silicon substrate is relieved, the upper limit of the peak nitrogen concentration being set so that a threshold shift does not occur at an interface between the silicon substrate and the oxide film.

An inventive semiconductor device is produced by the method according to the first aspect of the present invention.

### BRIEF DESCRIPTION OF THE DRAWINGS

FIG. 1 is a cross-sectional view of a semiconductor device according to Embodiment 1;

FIG. 2 is a graph showing the relationship between the stress and the dislocation density;

FIG. 3 is a graph showing the relationship between the peak nitrogen concentration and the stress in Embodiment 1;

FIG. 4 is a graph showing the relationship between the dislocation density and the junction leakage current;

FIG. 5 is a graph showing the relationship between the peak nitrogen concentration and the threshold voltage in Embodiment 1;

FIG. 6 is the profile of the nitrogen concentration in the oxide film in Embodiment 1;

FIG. 7 is a graph showing the relationship between the thickness of the oxide film and the optimal peak nitrogen concentration in Embodiment 1;

FIG. 8 is a graph showing the relationship between the peak nitrogen concentration and the stress in Embodiment 2;

FIG. 9 is a graph showing the relationship between the peak nitrogen concentration and the threshold voltage in Embodiment 2;

FIG. 10 is a graph showing the relationship between the thickness of the oxide film and the optimal peak nitrogen concentration in Embodiment 2;

FIG. 11 is the profile of the nitrogen concentration in the oxide film in Embodiment 2; and

FIG. 12 is a cross-sectional view of a known semiconductor device.

### DESCRIPTION OF THE PREFERRED EMBODIMENTS

A method for producing a semiconductor device of the present invention will be described below with reference to the drawings.

### Embodiment 1

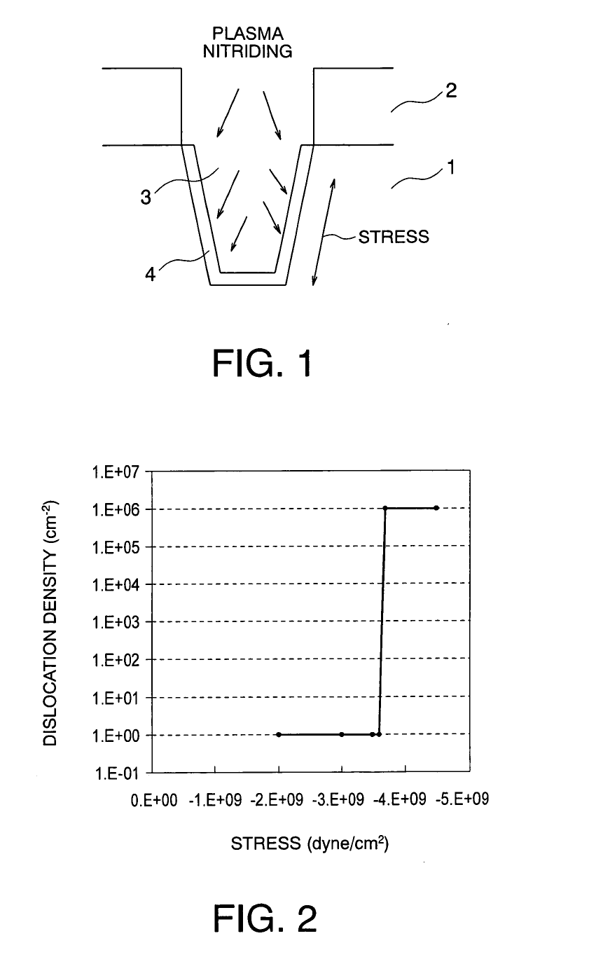

Embodiment 1 will now be described with reference to FIGS. 1 to 7. As shown in FIG. 1, a nitride film 2 is grown on a silicon substrate 1, and a trench 3 is formed by etching. The inner walls of the trench 3 are thermally oxidized to form inner-wall oxide films 4 each having a thickness of 5 to 20 nm. Then, the inner-wall oxide films 4 are partially nitrided by plasma to produce oxynitride films. A plasma oxide film is formed in the trench by plasma oxidation so as to be embedded in the entire trench. As a result, an isolation region for isolating elements from each other is produced. The peak nitrogen concentration in each oxynitride film is controlled to be optimized. By optimizing the peak nitrogen concentration, it is possible to reduce a stress and thus to suppress the occurrence of the dislocation defect in the silicon substrate. It is also possible to suppress a threshold voltage shift due to the positive charge of nitrogen.

Nitrogen in the oxynitride film functions as a positive charge. The presence of nitrogen at a silicon interface significantly affects transistor characteristics. Thus, the amount of nitrogen at the silicon interface is preferably minimized. The peak in the profile of the nitrogen concentration is preferably positioned as far away from the silicon interface as possible. The nitrogen concentration is preferably 1E20 (cm⁻³) or less at the silicon interface. The peak position in the profile of the nitrogen concentration in the inner-wall oxide film is preferably 1 nm away from the silicon interface. In addition, in order to effectively relieve the stress on the silicon interface with nitrogen, the peak position in the profile of the nitrogen concentration is preferably the inside of the inner-wall oxide film. More preferably, the peak position in the inner-wall oxide film is 1 nm or more away from an interface between the inner-wall oxide film and the plasma oxide film.

A sample wafer including an inner-wall oxide film having a thickness of 20 nm is nitrided by plasma nitriding with, for example, a unit that generates a plasma above and away from the wafer. The conditions of the plasma nitriding are as follows: plasma power, 1.5 kW; substrate temperature, 400° C.; distance between plasma and wafer, 60 mm; atmosphere, diluted gas containing nitrogen; pressure, 500 mTorr; and treatment time, 40 seconds. As a result of this plasma nitriding, the peak position in the profile of the nitrogen concentration is 1.5 nm away from the surface of the inner-wall oxide film, the peak nitrogen concentration is 5E21 (cm⁻³), and the nitrogen concentration at the silicon interface is 5E19 (cm⁻³).

The treatment time and the pressure among the production conditions are mainly controlled to optimize the peak position in the profile of nitrogen concentration in the oxynitride film and the peak nitrogen concentration. The peak nitrogen concentration is proportional to the treatment time. A longer treatment time results in a higher peak nitrogen concentration. When the treatment time is 300 seconds, the peak nitrogen concentration is 2E22 (cm⁻³). The peak position in the profile of the nitrogen concentration depends on the pressure. A higher pressure results in a deeper peak position. The peak is positioned at 3 nm deep at a pressure of 1,000 mTorr. The treatment time and the pressure can be easily adjusted without the modification of the apparatus configuration. Thus, the optimization by controlling the treatment time and the pressure has a number of advantages. However, any other production conditions may be adjusted to optimize the peak position and the peak nitrogen concentration.

The stress on the silicon substrate, the dislocation in the silicon substrate, the peak nitrogen concentration, and the threshold voltage (Vth) of the transistor will be described below with reference to FIGS. 2 to 6. FIG. 2 is a graph showing the relationship between the stress on the silicon substrate and the dislocation density in the silicon substrate. When the stress on the silicon substrate exceeds a specific value, the dislocation occurs. The minus sign in the value of the stress means a tensile stress on the silicon substrate. The dislocation occurs above a stress of −3.6E+09 (dyne/cm²) (critical stress). Therefore, a stress of −3.6E+09 (dyne/cm²) or less is needed to prevent the dislocation.

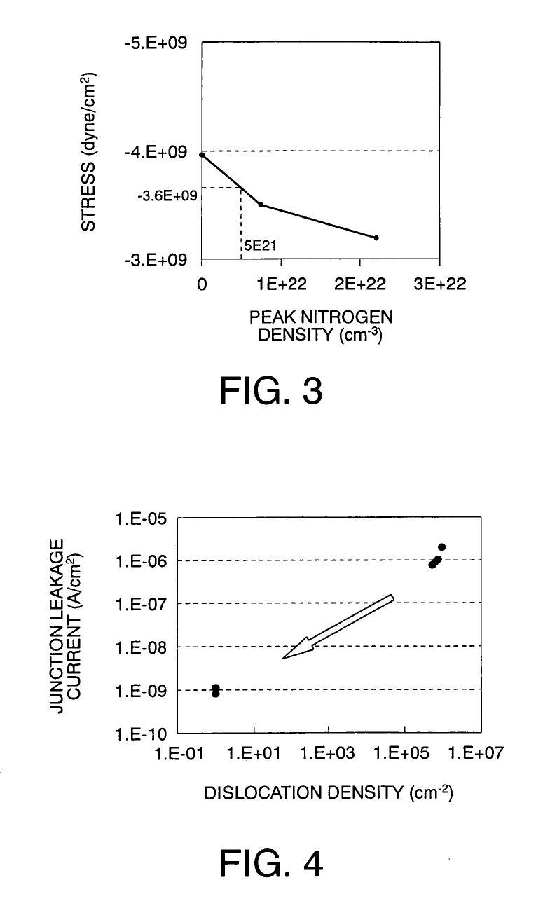

FIG. 3 is a graph showing the relationship between the peak nitrogen concentration and the stress with respect to a sample including a trench with inner-wall oxide films each having a thickness of 20 nm. The oxide films are converted into oxynitride films by nitriding. Each of the oxide films provides a tensile stress on the silicon substrate. On the contrary, a nitride film provides a compressive stress. When the nitrogen concentration is increased to produce oxynitride film, the tensile stress is canceled by the compressive stress. As a result, the stress on the silicon substrate is reduced. A critical stress is achieved at a peak nitrogen concentration of 5E21 (cm⁻³). When a peak nitrogen concentration is 5E21 (cm⁻³) or more, a stress on the silicon substrate is the critical stress or less. Thus, the dislocation does not occur. The peak nitrogen concentration is adjusted depending on the thickness of each oxide film on the corresponding inner wall of the trench. An oxide film having an increased thickness requires a high peak nitrogen concentration, while an oxide film having a reduced thickness requires a low peak nitrogen concentration.

The lower limit of the peak nitrogen concentration is set so that the stress on the silicon substrate is relieved. Nitriding is performed so that the peak nitrogen concentration is the lower limit or higher. The total concentration of nitrogen in each oxide film may also be used as an indicator to reduce the stress on the silicon substrate. However, a peak nitrogen concentration is used as the indicator in the present invention.

FIG. 4 is a graph showing the relationship between the dislocation density and the junction leakage current. The dislocation in the silicon crystal results in the occurrence of the leakage current. Therefore, it is necessary to prevent the occurrence of the dislocation and the leakage current. It is important to reduce the stress for preventing the dislocation from occurring. That is, it is important to convert the oxide film into the oxynitride film by nitriding for reducing the stress.

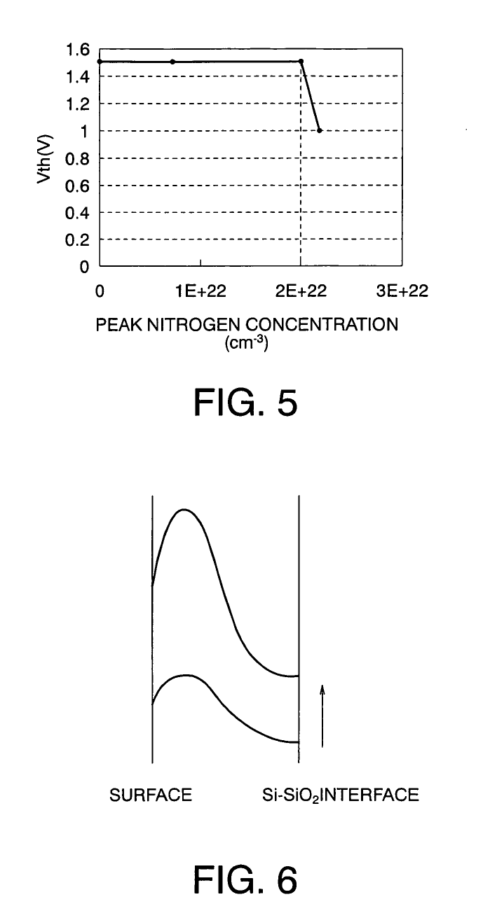

FIG. 5 is a graph showing the relationship between the peak nitrogen concentration and the threshold voltage (Vth) of the transistor. The threshold voltage (Vth) of the transistor decreases with an increase in the nitrogen concentration of the oxynitride film. For an inner-wall oxide film having a thickness of 20 nm, it is found that the threshold voltage is reduced at a peak nitrogen concentration of 2E+22 (cm⁻³). For an oxide film having a smaller thickness, the threshold voltage is reduced from a lower peak nitrogen concentration. The reduction in threshold voltage results in the generation of a leakage current at an interface between the shallow trench and the active region.

Thus, setting the upper limit of the peak nitrogen concentration is required. The threshold voltage is reduced under the following conditions: plasma power, 1.5 kW; substrate temperature, 100° C.; distance between plasma and wafer, 45 mm; pressure, 1 Torr; and treatment time, 300 seconds. The upper limit of the peak nitrogen concentration is set so that a threshold voltage is not reduced. Nitriding is performed so that the peak nitrogen concentration is the upper limit or less.

FIG. 6 is the profile of the nitrogen concentration in the oxide film. In plasma nitriding, the peak position in the profile of the nitrogen concentration is mainly adjusted by controlling the pressure, and the peak nitrogen concentration is mainly adjusted by controlling the treatment time. A higher pressure results in a deeper peak position. For example, the peaks are positioned at 1.5 nm deep and 3 nm deep at a pressure of 500 mTorr and 1,000 mTorr, respectively. A longer treatment time results in a higher peak nitrogen concentration. Peak nitrogen concentrations of 5E+21 and 2E+22 (cm⁻³) are obtained at 40 seconds and 200 seconds of the treatment time, respectively. Plasma nitriding is a kind of low-energy ion implantation. The plasma nitriding provides a sharp distribution of nitrogen compared with that of ion implantation. Furthermore, the plasma nitriding has an advantage that the plasma unit is simple compared with the unit of the ion implantation.

As described above, each of the inner-wall oxide films on the corresponding inner wall of the shallow trench is partially nitrided by plasma nitriding to produce an oxynitride film. This reduces the stress on the silicon substrate and prevents the occurrence of the crystal defect and the dislocation. However, excessive nitriding results in the shift of the threshold voltage and the occurrence of the leakage current due to charge trapping in the oxynitride film. Thus, to nitride the oxide film, it is necessary to optimize the peak nitrogen concentration corresponding to the thickness of the oxide film.

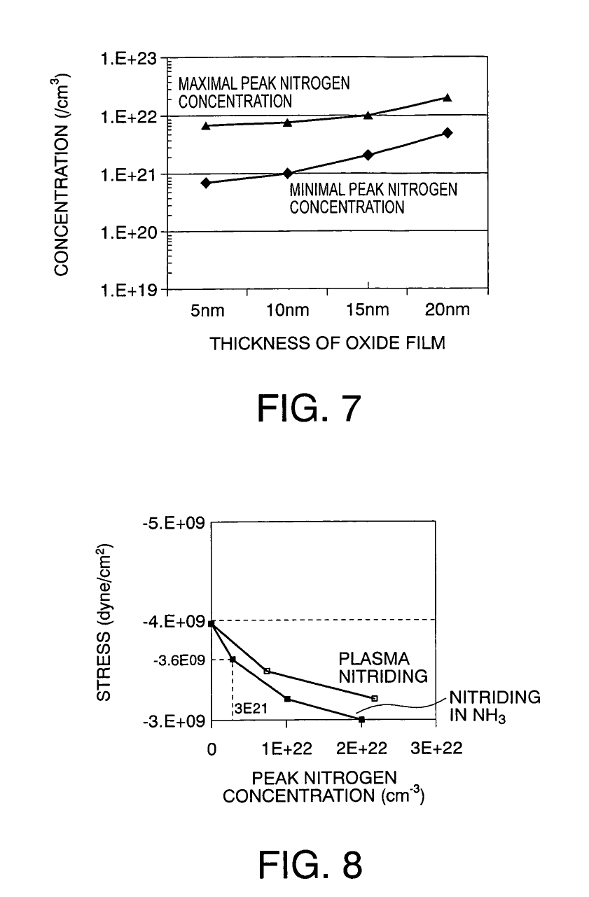

FIG. 7 shows the range of the optimal peak nitrogen concentration in the plasma nitriding. The optimal peak nitrogen concentration differs depending on the thickness of the oxide film. When the thicknesses of the oxide films are 5, 10, 15, and 20 nm, the range of the optimal peak nitrogen concentrations are 7E+20 to 7E+21 (cm⁻³), 1E+21 to 8E+21 (cm⁻³), 2E+21 to 1E+22 (cm⁻³), and 5E+21 to 2E+22 (cm⁻³), respectively.

In this embodiment, each of the oxide films on the corresponding inner wall of the shallow trench is partially nitrided by plasma to produce an oxynitride film. The peak nitrogen concentration in the oxynitride film is optimized. The optimal peak nitrogen concentration is in the range of the lower limit defined as a minimal peak nitrogen concentration required for preventing the occurrence of the dislocation in the silicon substrate to the upper limit defined as a maximal peak nitrogen concentration required for preventing the reduction in threshold voltage due to charge trapping in the oxynitride film. By setting the optimal peak nitrogen concentration, a method for producing a semiconductor device is provided, the method preventing the characteristic deterioration of the semiconductor device. In addition, a semiconductor device is produced without the characteristic deterioration by the method.

### Embodiment 2

Embodiment 2 will be described below with reference to FIGS. 8 to 11. In Embodiment 1, each of the inner-wall oxide films 4 shown in FIG. 1 is nitrided by plasma to produce an oxynitride film. However, in this Embodiment 2, each of the inner-wall oxide films 4 is heat-treated in a nitrogen-containing atmosphere to produce an oxynitride film.

Each oxide film having a thickness of 5 to 20 nm is heat-treated in an atmosphere containing, for example, NH₃, NO, or N₂O to produce an oxynitride film. Heat-treating for nitriding the oxide film provides a broad distribution of the nitrogen concentration compared with plasma nitriding. The nitrogen concentration is increased at a Si—SiO₂ interface. Thus, the peak nitrogen concentration is reduced and is in the range of 3E21 to 1E22 (cm⁻³). This concentration is achieved by heat-treating in NH₃ at 950° C. for 60 seconds. In NO atmosphere, the concentration is achieved by heat-treating at 950° C. for 40 seconds under a pressure of 740 Torr.

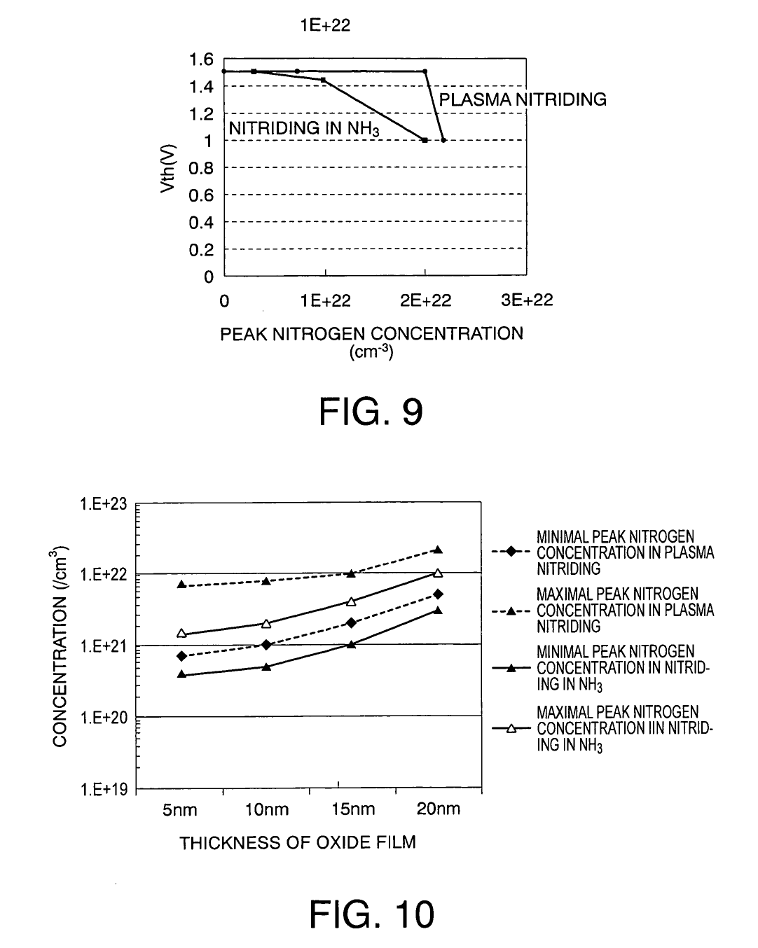

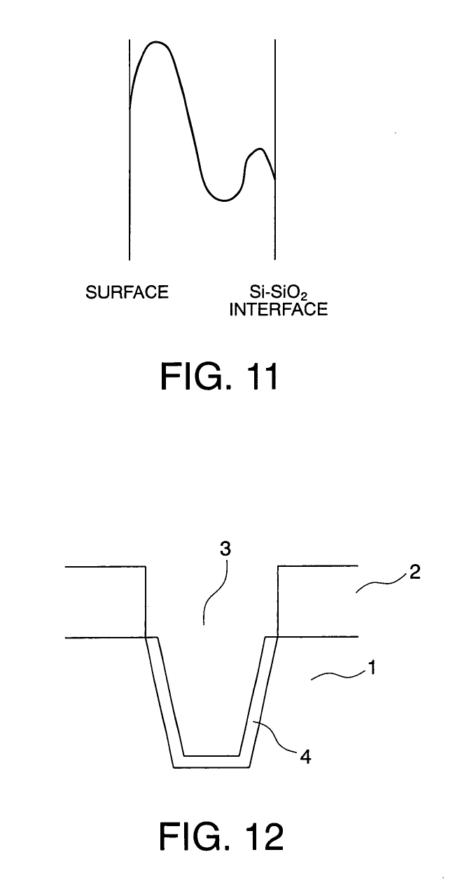

For an oxide film having a thickness of 20 nm, FIG. 8 shows the relationship between the peak nitrogen concentration and the stress, FIG. 9 shows the relationship between the peak nitrogen concentration and the threshold voltage (Vth), FIG. 10 shows the maximal and minimal peak nitrogen concentrations for the thickness of each oxide film on the corresponding inner wall of the trench, and FIG. 11 is the profile of the nitrogen concentration. As shown in FIG. 8, a peak nitrogen concentration of 3E21 (cm⁻³) or more is required to achieve a stress of −3.6E09 (dyne/cm²) or less. A peak nitrogen concentration of 5E21 (cm⁻³) is required to prevent the shift of the threshold voltage. However, the shift of the threshold voltage is admissible as long as the shift is within the product specification values. Thus, the peak nitrogen concentration of 1E22 (cm⁻³) is defined as the upper limit. The shift of the threshold voltage slightly occurs at this concentration.

In the case of an NH₃ or NO atmosphere, a peak nitrogen concentration of 5E21 (cm⁻³) or less is achieved by heat-treating at 1,050° C. for 15 seconds or less. By heat-treating at 1050° C. for 100 seconds, the resulting peak nitrogen concentration exceeds an upper limit of 1E22 (cm⁻³). Therefore, when the thicknesses of the oxide films are 20, 15, 10, and 5 nm, the optimal peak nitrogen concentrations are 3E21 to 1E22 (cm⁻³), 1E21 to 4E21 (cm⁻³), 7E20 to 2E21 (cm⁻³), and 4E20 to 1.5E21 (cm⁻³), respectively.

FIG. 11 shows the profile of the nitrogen concentration. A peak of the nitrogen concentration is present near the surface of the oxide film. Furthermore, a second peak of the nitrogen concentration is present near the interface between the silicon substrate and the oxide film. For a peak nitrogen concentration of 5E21 (cm⁻³), the peak position is 1.5 nm deep from the surface, the nitrogen concentration at the interface is 8E19 (cm⁻³), and the second peak position is 1 nm from the interface. Since the nitrogen distribution is broad, the total amount of nitrogen in the entire film is high. Thus, a minimal peak nitrogen concentration required for preventing the occurrence of the dislocation in the silicon substrate may be reduced. Furthermore, since the second peak is present near the interface between the silicon substrate and the oxide film, in order to achieve a nitrogen concentration of 1E20 (cm⁻³) or less at the interface, a maximal peak nitrogen concentration is also reduced. Nitrogen easily reaches the silicon interface by heat-treating at a high temperature. Thus, the optimal peak nitrogen concentration is difficult to be achieved. Prolonging the treatment time facilitates optimization of the peak nitrogen concentration. Heat-treating is preferably performed at 900° C. or less for 30 minutes or more.

In this Embodiment, each of the inner-wall oxide films on the corresponding inner wall of the shallow trench is partially heat-treated in a nitrogen-containing atmosphere to produce an oxynitride film. The peak nitrogen concentration in the oxynitride film is optimized. The lower limit is defined as a minimal peak nitrogen concentration required for preventing the occurrence of the dislocation in the silicon substrate. The upper limit is defined as a maximal peak nitrogen concentration required for preventing the reduction in threshold voltage due to charge trapping in the oxynitride film. By setting the lower limit and the upper limit, a method for producing a semiconductor device is provided, the method preventing the characteristic deterioration of the semiconductor device. In addition, a semiconductor device is produced without the characteristic deterioration by the method.

The present invention has been described in detail based on Embodiments, and it is to be understood that the present invention is not limited to these Embodiments. The present invention is intended to cover various modifications and equivalent arrangements included within the scope of the invention. For example, nitriding may be performed after the oxide film formed by plasma oxidation is embedded in the trench. The distance between the surface of the oxide film embedded and the silicon interface is increased; hence, the heat-treating can be performed at a higher temperature. To relieve the stress, the treatment time required for introducing an amount of nitrogen needed may be a shorter time. It is possible to achieve the introduction by heat-treating at 1,000° C. for 20 minutes.

1. A method for producing a semiconductor device including a trench formed by trench isolation, comprising a step of:
nitriding an oxide film on an inner wall of the trench, the lower limit of the peak nitrogen concentration being set so that stress on a silicon substrate is relieved, the upper limit of the peak nitrogen concentration being set so that a threshold shift does not occur at an interface between the silicon substrate and the oxide film.

2. The method for producing a semiconductor device according to claim 1, wherein the lower limit of the peak nitrogen concentration is 4E20 (cm⁻³) and the upper limit of the peak nitrogen concentration is 2E22 (cm⁻³).

3. The method for producing a semiconductor device according to claim 1, wherein the nitriding is performed by plasma nitriding or thermal treatment in an ammonia (NH₃), a nitric oxide (NO), or a nitrous oxide (N₂O) atmosphere.

4. The method for producing a semiconductor device according to claim 3, wherein the nitriding is performed by the plasma nitriding, the lower limit of the peak nitrogen concentration being set at 7E20 (cm⁻³), and the upper limit of the peak nitrogen concentration being set at 2E22 (cm⁻³).

5. The method for producing a semiconductor device according to claim 3, wherein the nitriding is performed by the thermal nitriding in an NH₃, NO, or N₂O atmosphere, the lower limit of the peak nitrogen concentration being set at 4E20 (cm⁻³) and the upper limit of the peak nitrogen concentration being set at 1E22 (cm⁻³).

6. The method for producing a semiconductor device according to claim 1, wherein the nitriding is performed so that the nitrogen concentration is 1E20 (cm⁻³) or less at the interface between the oxide film and the silicon substrate.

7. The method for producing a semiconductor device according to claim 6, wherein the nitriding is performed so that the peak position in the profile of the nitrogen concentration in the oxide film is 1 nm or more away from the interface between the oxide film and the silicon substrate.

8. A semiconductor device produced by the method according to claim 1.

9. A semiconductor device produced by the method according to claim 4.

10. A semiconductor device produced by the method according to claim 5.

11. A semiconductor device produced by the method according to claim 6.

12. A semiconductor device produced by the method according to claim 7.
